(19) United States
(12) Patent Application Publication
(10) Pub. No.: US 2026/0004028 A1
(43) Pub. Date: Jan. 1, 2026

(54) METHOD FOR DETERMINING AT LEAST ONE CELL PARAMETER OF A CELL SYSTEM, A CELL SYSTEM, AND A COMPUTER PROGRAM

(71) Applicant: Robert Bosch GmbH, Stuttgart (DE)

(72) Inventors: Felix Eberhard Hildebrand, Stuttgart-West (DE); Alexander Konstandin, Binau (DE); Christoph Zimmer, Stuttgart (DE); Ingo Kerkamm, Stuttgart (DE); Markus Klinsmann, Stuttgart (DE); Sebastian Egger, Radolfzell Am Bodensee (DE)

(21) Appl. No.: 18/880,964

(22) PCT Filed: Jun. 26, 2023
(86) PCT No.: PCT/EP2023/067255

§ 371 Date: Jan. 3, 2025

(30) Foreign Application Priority Data
Jul. 4, 2022 (DE) 10 2022 206 797.5

(51) Int. Cl. G06F 30/27

(52) U.S. Cl. CPC G06F 30/27

(57) ABSTRACT

The invention proceeds from a method for determining at least one cell parameter, in particular an aging parameter, of a cell system (30) comprising at least one electrochemical cell (32).

It is proposed that the cell parameter be determined based on a physical model of the cell system (30) depending on operational parameters of the cell system (30).

(FIG. 2)

### BACKGROUND

A method for determining at least one cell parameter of a cell system comprising at least one electrochemical cell has already been proposed.

### SUMMARY

The invention proceeds from a method for determining at least one cell parameter, in particular an aging parameter of a cell system comprising at least one electrochemical cell.

It is proposed that the cell parameter be determined based on a physical model of the cell system as a function of operational parameters of the cell system.

By the embodiment of the method according to the invention, the at least one cell parameter or a plurality of cell parameters of the cell system can be determined computationally and in particular without using a sensor based on the operational parameters of the cell system. Advantageously, the at least one cell parameter can be determined with a particularly low need for the use of sensor technology. Advantageously, the cell system can be operated particularly efficiently, precisely and/or carefully on the basis of the determined cell parameter. For example, at least one aging state of the cell system may advantageously be determined. Advantageously, an anticipated failure time of the cell system can be estimated. Advantageously, a maintenance time for the cell system can be adjusted particularly precisely to a maintenance requirement of the cell system. Advantageously, a manufacturing process of cell systems can be adjusted, in particular optimized, particularly precisely and efficiently in terms of time based on the at least one determined cell parameter.

The electrochemical cell is preferably formed as a solid oxide fuel cell. Alternatively, however, it is also contemplated that the electrochemical cell may be formed as another fuel cell, for example a polymer electrolyte membrane fuel cell or the like, as an electrolytic cell or as an accumulator cell. For example, alternatively, it is also contemplated that the electrochemical cell is used in an electrolyzer. It is contemplated that the cell system comprises only one, in particular the electrochemical cell already mentioned above, or that the cell system comprises a plurality of electrochemical cells, for example two, three or several hundred electrochemical cells. Preferably, the electrochemical cells of the cell system comprising a plurality of electrochemical cells are aggregated into a stack and in particular connected in series. It is also contemplated that the cell system comprises a plurality of stacks formed from a plurality of electrochemical cells, preferably aggregated to form a module or tower.

The physical model is preferably a simulation model of the cell system, which in particular describes a steady state operation of the cell system. Preferably, the physical model is based on the finite element method. The physical model in particular is unambiguously invertable with regard to the at least one cell parameter, preferably the aging parameter. It is contemplated that the physical model may be unambiguously invertable with respect to the at least one cell parameter, preferably the aging parameter, by filtering out physically irrelevant results of the physical model. For example, according to a publication by Zaccaria, Tucker and Traverso entitled “A distributed real-time model of degradation in a solid oxide fuel cell” (2016, Journal of Power Sources 311, 175-181), the physical model may describe a degradation of the cell system comprising solid oxide fuel cells, wherein an ohmic portion of internal voltage losses is assigned the aging parameter as a pre-factor. Alternatively, it is also conceivable, for example, that other resistors of internal voltage losses differing from the ohmic portion, in particular the concentration losses or polarization losses, of the cell system or an overall internal resistance of the cell system, are multiplied by the aging parameter as a pre-factor. In the preferred physical model, in particular, an overall specific surface resistance of the cell system is multiplied by the aging parameter. The aging parameter in particular describes aging state of the cell system. For example, in an unaged state of the cell system, the aging parameter has a value of 1, and preferably a value greater than 1, for an aged state of the cell system. The aging parameter is preferably a scalar parameter.

In particular, the physical model has at least one input parameter and at least one output parameter. Preferably, the at least one input parameter of the physical model comprises at least one of the operational parameters of the cell system, in particular at least one input parameter of the cell system, preferably at least one operating parameter of the cell system. Preferably, at least one further input parameter of the physical model is the cell parameter, preferably the aging parameter. For example, the operating parameter is a requested load current, a temperature, particularly a gas temperature, a volumetric flow rate, an air efficiency level, a fuel efficiency level, a gas composition, a pressure, a pressure difference, or the like. Preferably, the at least one output parameter of the physical model comprises at least one operational parameter of the cell system, in particular at least one output parameter of the cell system, preferably at least one performance parameter of the cell system. The performance parameter of the cell system is in particular an output voltage of the electrochemical cell, preferably the stack formed by a plurality of electrochemical cells. It is contemplated that the output parameters of the physical model comprise at least one further cell parameter, in particular at least one internal parameter, of the cell system.

For example, the internal parameter is an internal temperature parameter of the cell system. The internal temperature parameter is preferably a temperature of the cell system, preferably of the at least one electrochemical cell or stack formed by a plurality of electrochemical cells. The internal parameter is in particular a local field size. Alternatively, it is contemplated that the internal parameter is, for example, a fluid distribution, preferably an oxygen distribution or a hydrogen distribution, in the cell system, a current density distribution in the cell system, or the like. In particular, the physical model depicts a mapping which maps the input parameters of the physical model, preferably the at least one operating parameter of the cell system and the aging parameter of the cell system, to the output parameters of the physical model, preferably the at least one performance parameter of the cell system, and in particular the at least one further cell parameter of the cell system, preferably the at least one internal parameter.

The cell system preferably comprises a control unit. The control unit is in particular provided to perform the method of determining the at least one cell parameter. The term “provided” is preferably intended to mean specifically designed, specifically configured, and/or specifically equipped. An object being provided or designed for a specific function is understood to mean that the object fulfills and/or performs this specific function in at least one application and/or operating state. In particular, the control unit comprises at least one processor and one memory element, as well as an operating program stored on the memory element. The memory element is preferably designed as a digital storage medium, e.g., a hard disk or the like. In particular, the cell system comprises a housing in which preferably the at least one electrochemical cell or stack formed by a plurality of electrochemical cells is disposed. It is contemplated that the control unit is disposed at least partially on, in particular at least partially in, the housing. Alternatively or additionally, it is also contemplated that the cell system comprises an external unit, wherein the external unit comprises at least a part of the control unit. For example, the external unit may be a cloud, a server, or the like. It is contemplated that the operational parameters will be transmitted to the external unit, for example wirelessly or via a cable, wherein the external unit preferably determines the at least one cell parameter of the cell system depending on the operational parameters of the cell system based on the physical model. It is also contemplated that the external unit comprises the memory element of the control unit.

It is further proposed that the operational parameters comprise at least one, in particular the previously mentioned input parameter of the cell system. It is contemplated that the operational parameters, depending on which the cell parameter is determined depending on the physical model of the cell system, only have one input parameter of the cell system or a plurality of input parameters of the cell system. Advantageously, particularly easy-to-sense parameters of the cell system, in particular the at least one input parameter of the cell system, can be used to determine the cell parameter. Advantageously, the cell parameter can be determined with a particularly low level of technical effort.

Furthermore, it is proposed that the input parameter comprises at least one, in particular the aforementioned, operating parameter of the cell system. In particular, the input parameter corresponds to the operating parameter. It is contemplated that the at least one operating parameter is a variable or a control variable, in particular an actual value or a target value of the control variable, of the cell system. Advantageously, particularly easy-to-sense parameters of the cell system, in particular the at least one operating parameter of the cell system, can be used to determine the cell parameter. Advantageously, the cell parameter can be determined with a particularly low level of technical effort. Advantageously, at least in some cases parameters of the cell system that are needed and sensed for an operation of the cell system can be used to determine the cell parameter.

In addition, it is proposed that the operational parameters comprise at least one, in particular the previously mentioned, output parameter of the cell system. It is contemplated that the operational parameters comprise only the one output parameter of the cell system or a plurality of output parameters of the cell system, depending on which the cell parameter determined based on the physical model of the cell system. Advantageously, particularly easy-to-sense parameters of the cell system, in particular the at least one output parameter of the cell system, can be used to determine the cell parameter. Advantageously, the cell parameter can be determined with a particularly low level of technical effort. Advantageously, at least in some cases parameters of the cell system that are needed and sensed for an operation of the cell system can be used to determine the cell parameter.

It is also proposed that the output parameter comprises at least one, in particular the performance parameter of the cell system already mentioned above. In particular, the output parameter corresponds to the performance parameter of the cell system. Advantageously, particularly easy-to-sense parameters of the cell system, in particular the at least one performance parameter of the cell system, can be used to determine the cell parameter. Advantageously, the cell parameter can be determined with a particularly low level of technical effort. Advantageously, at least in some cases parameters of the cell system that are already sensed for an operation of the cell system can be used to determine the cell parameter.

Further, it is proposed that the operational parameters be sensed at least in part on the cell system. Preferably, at least the performance parameter, in particular the output voltage, of the cell system is sensed on the cell system, preferably using sensors. Preferably, the cell system comprises a sensing unit for at least partially sensing the operational parameters. The sensing unit is preferably connected to the control unit via data technology, in particular for wireless and/or wired data transmission. It is also contemplated that the control unit at least partially comprises the sensing unit. It is contemplated that the operational parameters configured as input parameters of the cell system and/or the operational parameters configured as output parameters of the cell system are sensed at least in part, preferably via sensor technology, preferably by means of the sensing unit. For example, the sensing unit comprises at least one sensor unit for at least partially sensing the operational parameters. The sensing unit is preferably configured to sense at least the output parameter configured as the performance parameter, in particular using sensors. For example, the sensor unit comprises at least one voltage sensor, in particular for sensing the performance parameter of the cell system configured as the output voltage. It is contemplated that the sensing unit is configured to detect at least one input parameter of the cell system configured as operating parameters. Additionally or alternatively, it is conceivable that the at least one input parameter, preferably the input parameter configured as a variable or control variable, in particular the target value of the input parameter configured as the control variable, is read directly via the control unit, preferably provided by the control unit. Advantageously, the at least one cell parameter can be determined particularly precisely. Advantageously, the cell system can be operated particularly efficiently, precisely and/or carefully on the basis of the particularly cell parameter which can be determined particularly precisely.

It is further proposed that time series be formed from the operational parameters. Preferably, in a method step, in particular in a sensing step, the operational parameters, preferably the at least one input parameter and the at least one output parameter are recorded over time. Preferably, the recorded operational parameters are stored as time series on the control unit, in particular on the memory element of the control unit. Advantageously, the cell parameter can be calculated at any time at different times from the time series of the operational parameters. Advantageously, the cell parameter can be determined particularly conveniently. Advantageously, the cell parameter can be calculated and evaluated for different points in time.

Furthermore, it is proposed that the physical model be inverted and optimized to determine the cell parameter, in particular with respect to the cell parameter. Preferably, to determine the cell parameter, which is in particular one of the input parameters of the physical model, preferably to determine the aging parameter, the physical model is inverted and optimized, preferably with respect to the cell parameter, in particular the aging parameter. Preferably, in a method step, in particular in a selection step, a time is selected from the time series of the operational parameters, preferably by the control unit, wherein the control unit is particularly provided for determining the at least one cell parameter, preferably the aging parameter, for the selected point in time. Preferably, the control unit is provided to select the point in time from the time series of the operational parameters such that an associated system state of the cell system at the time can be described by the physical model. For example, it is conceivable that the physical model is only applicable to steady state conditions, in particular input parameters of the cell system, so that sufficient steady state operational parameters are to be used accordingly. It is also contemplated that the operational parameters may be at least partially pre-processed, for example oscillations or the like may be removed by a filter. It is contemplated that the operational parameters, in particular the at least one input parameter and the at least one output parameter, are at least partially aggregated. It is also contemplated that the operational parameters associated with the time may be at least partially converted by the control unit, preferably in a conversion step, for adjustment to the physical model. Preferably, the operational parameters associated with the time, in particular in the conversion step, are converted to the input parameters and/or output parameters of the physical model as needed. For example, it is contemplated that the cell system comprises a plurality of stacks, each comprising a plurality of electrochemical cells, wherein averaging is performed over the individual stacks or that a sensed current of the cell system is converted to a current density. The physical model is preferably used to determine, in particular in a determination step, the at least one cell parameter at a time, preferably the previously selected time, for which the physical model together with the at least one input parameter at the time, in particular the previously selected time, predicts the at least one, preferably the sensed, output parameter at the time, in particular the previously selected time. In particular, for determining the cell parameter, an optimization process, a Bayesian optimization, for example, a simulated annealing method, a gradient method or the like is used, preferably in the determining step, in particular with respect to the sensed output parameter of the cell system for the at least one input parameter of the, in particular the previously selected point in time and the output parameter predicted by the physical model with the input parameters of the selected point in time. Advantageously, the at least one cell parameter can be determined without using sensors from the operational parameters of the cell system. Advantageously, the cell parameter can be determined with a particularly low need for sensor technology.

In addition, it is proposed that the physical model is used to train a regression model. Preferably, the regression model is trained on the basis of results determined by the physical model, for example by means of statistical experimental planning. Preferably, the regression model, in particular in an alternative determining step, is provided for replacing the physical model. The regression model is provided in particular, preferably in the alternative determining step, for use in an optimization method for determining the at least one cell parameter or for directly determining the at least one cell parameter. In particular, it is contemplated that the regression model is trained such that the regression model determines the at least one cell parameter of the cell system directly from the operational parameters, preferably the at least one input parameter and the at least one output parameter, preferably in the alternative determination step, wherein in particular an inversion of the physical model, preferably at least in the determination step, is omitted. In particular, a statistical design is generated from a combination of operational parameters of the physical model, for example by means of Latin Hypercube Sampling, Active Learning or the like, for which the at least one cell parameter is determined based on the physical model, wherein results are used for training the regression model. For example, the training of the regression model is based on linear regression, on a random forest, on a Gaussian process, on a neural network, on an explainable boosting machine, or the like. Preferably, the at least one cell parameter is determined, in particular in an alternative determining step, using the regression model. Advantageously, the cell parameter can be determined particularly efficiently in terms of time and computational effort by means of the regression model.

It is also proposed that active learning, in particular safe active learning, be used to train the regression model. Active learning is particularly used to select training data with optimal information for training the regression model. Preferably, safe active learning is used to avoid training data at which the physical model does not converge, and in particular at which it diverges. Preferably, for example, when determining the at least one cell parameter, a convergence parameter is determined. The convergence parameter is preferably an indicator of how close, in particular numerically, a solution method for the physical model was to not converging, in particular to diverging. For example, the convergence parameter may be determined from a required number of iterations of the solution method to determine the at least one cell parameter. Alternatively, it is also conceivable that the convergence parameter is determined as a function of the physical model's output parameters, in particular as a function of the at least one output parameter of the cell system and/or as a function of the internal parameter. Preferably, in an initialization step to initialize the training of the regression model, cell system operational parameters are selected for a system state of the cell system for which it is known that the solution method for the physical model converges. Based on the physical model, in particular through an inversion and optimization of the physical model, preferably the at least one cell parameter is determined relative to the operational parameters selected in the initialization step. Preferably, a value for the convergence parameter associated with the results is determined based on results of the initialization step, in particular based on the operational parameters selected in the initialization step and the cell parameter determined in the initialization step. The model is trained based on the results from the initialization, in particular, the, preferably probabilistic, regression model, preferably a Gaussian process model. Preferably, an additional, in particular probabilistic safety model, preferably a Gaussian process is trained based on the value determined in the initialization step for the convergence parameter. Preferably, a loop is executed after the initialization step to train the regression model. The loop preferably comprises a first loop step in which operational parameters are selected for a further system state of the cell system, which preferably have a maximum value for an information content and with which the method of solving the physical model converges with a probability that is in particular above a probability threshold. Very particularly preferably, the probability threshold is 0.5. Alternatively, however, it is also conceivable that the probability threshold is between 0.1 and 0.9, preferably between 0.2 and 0.8, preferably between 0.3 and 0.7, particularly preferably between 0.4 and 0.6. However, further alternatively, it is also conceivable that the probability threshold is outside a value range of between 0.1 and 0.9. The information content is preferably evaluated via entropy, which is proportional to the predictive variance, especially in the case of Gaussian processes. In particular, a limited optimization problem arises in which the operational parameters are calculated, in which the information content has a maximum value and the probability of convergence of the solution method for the physical model is greater than the probability threshold. The probability threshold is preferably adjustable by an operator, for example via an input unit. Preferably, the input unit is connected or connectable to the control unit via data technology, in particular for wireless and/or wired data transmission. For example, the input unit may be configured as a keyboard, a keypad, a touch screen, a rotary dial, a slider, a push button, or the like. It is contemplated that the control unit or the external unit comprises the input unit. As an alternative to the probability of convergence of the solution method for the physical model for determining the at least one cell parameter, a criterion is also conceivable that a probability for an interference-free simulation using the physical model is greater than the probability threshold. The probability of a fault-free simulation using the physical model preferably considers the convergence of the solution method for the physical model, memory requirements, processor requirements, and a simulation duration. Alternatively, or in addition, a distance of the cell parameters determined by the physical model from known physical limits can also be used as an indicator of the probability of a fault-free simulation. In a second loop step of the loop, the at least one cell parameter and a corresponding value for the convergence parameter are determined with the operating parameters of the further system state. Preferably, in a third loop step of the loop, the regression model and/or the safety model is updated as a function of the at least one cell parameter determined in the second loop step and/or as a function of the value for the convergence parameter determined to the further system state of the cell system. If no termination criterion is satisfied after the third loop step, the loop begins again with the first loop step. For example, the termination criterion may be an exhaustion of the computational time, an exhaustion of a number of evaluated system states of the cell system, a drop of the information content below a threshold value for the information content, or a drop of a maximum error on a validation data set to below a threshold. It is contemplated that the threshold value may be adjustable for the information content, for example automatically by the control unit or manually by the operator via the input unit. It is also contemplated that, during a calculation of the physical model, several system states are selected and, in particular, calculated in parallel, wherein an entropy of a Gaussian process is proportional to the predictive covariance. The predictive covariance may preferably be mapped to a one-dimensional variable for optimization by means of optimality criteria, for example by means of determinants, preferably by means of maximum intrinsic value. Further, it is contemplated that, particularly in the case of a plurality of system states to be calculated in parallel using the model, a Greedy algorithm is applied. Further, it is also contemplated that calculations will be performed at a delay using the physical model. Advantageously, the regression model can be trained particularly efficiently. Advantageously, the at least one cell parameter can be determined particularly efficiently.

It is further proposed that a time curve of a, in particular the aforementioned, aging parameter of the cell system is determined. In addition or alternatively, it is also conceivable that a time curve of the at least one further cell parameter of the cell system, in particular a time curve of the at least one internal parameter of the cell system, is determined. Preferably, the aging parameter is determined as a function of the operational parameters of the cell system based on the physical model at a further point in time, in particular at a plurality of further points in time, preferably from the time series of the operational parameters, preferably analogously to the determination of the aging parameter at the previously selected point in time. Based on the determined aging parameter at different times, the curve of the aging parameter over time can be determined and in particular presented. It is contemplated that the curve of the aging parameter over time is extrapolated, in particular to predict a future course of the aging parameter. It is also contemplated that the curve of the aging parameter over time is related to at least one, preferably aging-relevant, operational parameter of the cell system and/or internal parameter of the cell system. Advantageously, an aging rate of the cell system can be determined and monitored based on the curve of the aging parameter over time. Advantageously, a possible failure time of the cell system can be predicted.

In addition, it is proposed that at least one, in particular the already mentioned further cell parameter, preferably the at least one internal parameter, of the cell system is determined depending on the determined cell parameter. Preferably, the at least one further cell parameter, preferably the at least one internal parameter of the cell system, which is in particular one of the output parameters of the physical model, is determined based on the physical model determined depending on the aging parameter through inverting and optimizing the physical model with respect to the aging parameter or by the regression model generated by the physical model. Advantageously, the cell system can be operated particularly efficiently, precisely and/or carefully on the basis of the determined further cell parameter. Advantageously, cell parameters that require a particularly high use of sensor technology to be sensed can be determined particularly easily.

Furthermore, it is proposed that the at least one further cell parameter is determined in a spatially resolved manner. Preferably, the local distribution of the further cell parameter determined as an internal parameter is determined. The local distribution of the at least one further cell parameter is in particular a local distribution of the at least one further cell parameter within the cell system, preferably within the at least one electrochemical cell or within the stack formed from a plurality of electrochemical cells. Preferably, the local distribution of the at least one further cell parameter is determined based on the physical model as a function of operational parameters of the cell system, preferably via the optimization method applied to the inverted physical model with respect to the aging parameter or via the regression model generated by the physical model. In particular, the at least one further cell parameter, preferably the internal parameter, can be determined at a position or at a list of positions in the cell system. It is also contemplated that a combination of a plurality of further cell parameters of the cell system, preferably of a plurality of internal parameters of the cell system, for example a product, a sum, a non-linear function or the like, may be determined at the position or at the list of positions in the cell system. It is also contemplated that that derived values of the at least one further cell parameter or of the combination of the plurality of further cell parameters, for example a maximum, a minimum an average in a partial volume or in a total volume of the cell system, are determined to describe the distribution, for example a first degree surface torque, a second degree surface torque, support points of a cumulative distribution density or the like, gradients or rates of change. Advantageously, knowledge of the local distribution of the at least one further cell parameter allows for an increase in an efficiency and a dynamism of the cell system, for example by using an optimization of an operating strategy for the cell system. Advantageously, a particularly careful, precise and efficient operation of the cell system can be realized.

In addition, it is proposed that the at least one further cell parameter comprises a temperature distribution in the cell system. It is contemplated that the at least one further cell parameter corresponds to the temperature distribution in the cell system. Advantageously, knowledge of the temperature distribution in the cell system, in particular in the stack formed by a plurality of electrochemical cells or in the electrochemical cell, allows for ensuring compliance with predetermined limits for the distribution, for example for the minimum temperature and/or maximum temperature, to prevent local damage in the cell system. Advantageously, a particularly safe operation of the cell system can be realized. Advantageously, a particularly durable cell system can be provided.

It is also proposed that the at least one further cell parameter comprises a fluid distribution, in particular an oxygen distribution and/or a hydrogen distribution, in the cell system. It is contemplated that the at least one further cell parameter corresponds to the fluid distribution, in particular the oxygen distribution and/or the hydrogen distribution, in the cell system. Advantageously, knowledge of the fluid distribution, in particular the oxygen distribution and/or the hydrogen distribution, makes it possible to ensure compliance with predetermined limits for the distribution, for example for a minimum concentration for preventing local damage in the cell system. Advantageously, a particularly safe operation of the cell system can be realized. Advantageously, a particularly durable cell system can be provided.

It is further proposed that the at least one further cell parameter comprises a current density distribution in the cell system. It is contemplated that the at least one further cell parameter corresponds to the current density distribution in the cell system. Preferably, multiple cell parameters can be determined based on the physical model, depending on the operational parameters of the cell system, in particular the temperature distribution in the cell system, the fluid distribution in the cell system, the current density distribution in the cell system and/or the aging parameter of the cell system. Advantageously, knowledge of the current density distribution in the cell system makes it possible to ensure compliance with predetermined limits for the distribution, for example for a maximum current density, to counteract local damage in the cell system. Advantageously, a particularly safe operation of the cell system can be realized. Advantageously, a particularly durable cell system can be provided.

Further, it is proposed that the physical model be used to generate training data for a failure detection model. In particular, a critical value range is specified for the at least one further cell parameter, preferably the at least one internal parameter, which is stored, for example, on the memory element of the control unit. It is contemplated that the critical value range may be adjustable, for example automatically by the control unit or manually by the operator via the input unit. The physical model can in particular be used to determine the operational parameters for which the at least one further cell parameter, in particular the internal parameter, lies in the critical value range. By means of the physical model, for example, a database with the operational parameters and the associated values determined for the at least one further cell parameter, preferably an internal parameter, can be determined based in particular on the physical model. Preferably, the failure detection model can be purposefully trained using the database with operational parameters, in which the respective associated value of the at least one further cell parameter is within or outside the critical value range. Preferably, the failure detection model is trained by machine learning, in particular to perform a classification method for classifying determinable failure states of the cell system. For example, the training of the failure detection model is based on a random forest, on a support vector machine, on a neural network, or the like. Preferably, the failure detection model is used in the operation of the cell system to sense and in particular classify a failure state in the cell system based on the operational parameters of the cell system sensed in operation, for example to associate them with the at least one further cell parameter, preferably the at least one internal parameter. For example, with a plurality of further cell parameters, in particular a plurality of internal parameters of the cell system, it is conceivable that the failure detection model is trained such that it recognizes, based on the operational parameters of the cell system in operation, which of the plurality of further cell parameters, in particular a plurality of internal parameters, of the cell system lie within the respective critical value range. Advantageously, the failure detection model can be trained particularly precisely and efficiently. Advantageously, errors in the cell system can be detected particularly simply and reliably. Advantageously, a mapping of an error in the cell system to the at least one cell parameter is enabled.

Furthermore, a cell system, in particular the aforementioned cell system, is proposed with at least one, in particular the aforementioned electrochemical cell and with at least one, in particular the aforementioned control unit for performing the method according to the invention. Advantageously, a particularly durable cell system can be provided. Advantageously, a cell system can be provided, which enables particularly precise and convenient maintenance planning.

Furthermore, a computer program is proposed, comprising commands that, when the computer program is executed by a computer, prompt the latter to perform the method according to the disclosure. The computer program is preferably stored on the memory element of the control unit. Alternatively, it is also contemplated that the computer program may be stored on a portable data storage device, for example on a USB stick, on a portable hard drive, on an optical data storage device, in particular on a CD or the like, in a cloud, on a server, or the like. In particular, the control unit instructs the computer to carry out the computer program. Advantageously, a method for determining cell parameters of a cell system can be adjusted particularly conveniently and flexibly. Advantageously, the method can be applied to different cell systems, and in particular can be adapted to a specific cell system in a particularly convenient manner.

The method according to the invention, the cell system according to the invention and/or the computer program according to the invention is not intended to be limited to the application and embodiment described hereinabove. In particular, the method, the cell system according to the invention and/or the computer program according to the invention can comprise a number of individual elements, components, units, and method steps that deviates from a number specified herein for fulfilling a function described herein. Moreover, regarding the ranges of values indicated in this disclosure, values lying within the limits specified hereinabove are also intended to be considered as disclosed and usable as desired.

Further advantages follow from the description of the drawings hereinafter. The drawings illustrate an exemplary embodiment of the invention. The drawings, the description, and the disclosure contain numerous features in combination. A person skilled in the art will appropriately also consider the features individually and combine them into additional advantageous combinations.

### BRIEF DESCRIPTION OF THE DRAWINGS

Shown are:

FIG. 1 a schematic representation of a cell system according to the invention having at least one electrochemical cell and having at least one control unit for performing a method according to the invention for determining at least one cell parameter of the cell system,

FIG. 2 a schematic procedure of the method according to the invention,

FIG. 3 a schematic procedure for training a regression model using a physical model; and

FIG. 4 a schematic procedure for applying a failure detection model to the cell system.

### DETAILED DESCRIPTION

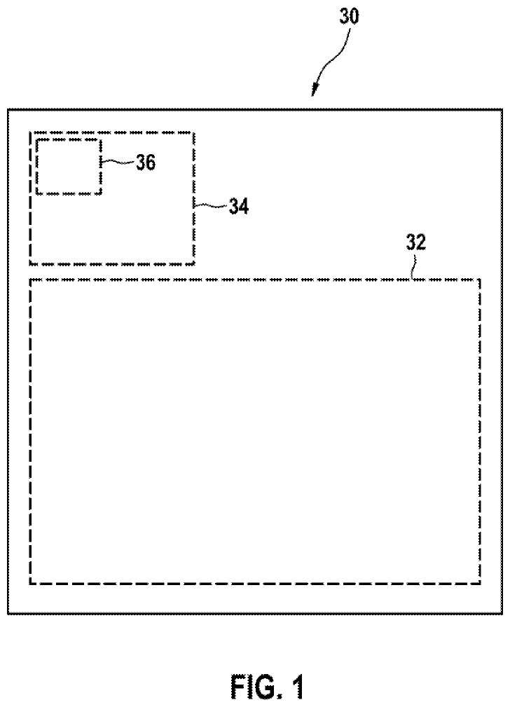

FIG. 1 shows a cell system 30 having a plurality of electrochemical cells 32 (by way of example, only one electrochemical cell 32 is shown in FIG. 1). Alternatively, it is also contemplated that the cell system 30 only comprises one electrochemical cell 32. The electrochemical cells 32 are aggregated into a stack. It is also contemplated that cell system 30 may comprise a plurality of stacks formed from a plurality of electrochemical cells 32, preferably aggregated to form a module or tower. The electrochemical cells 32 are connected in series. The electrochemical cells 32 are formed as solid oxide fuel cells. Alternatively, it is also contemplated that the electrochemical cells 32 may be formed as other types of fuel cells, such as polymer electrolyte membrane fuel cells or the like, as electrolytic cells, or as accumulator cells. For example, it is also contemplated that electrochemical cells 32 may be used in an electrolyzer.

The cell system 30 comprises at least one control unit 34. The control unit 34 is provided for performing a method of determining at least one cell parameter of the cell system 30, in particular for determining an aging parameter of the cell system 30, and for determining a plurality of further cell parameters of the cell system 30, in particular for determining a plurality of internal parameters of the cell system 30. Alternatively, it is also conceivable that only the cell parameter of the cell system 30, in particular the aging parameter, can be determined by the method. The control unit 34 comprises at least one processor (not shown here) and one memory element (not shown here) as well as an operating program stored on the memory element. The memory element is designed as a digital storage medium, e.g. as a hard disk or the like.

The cell system 30 comprises a housing (not shown here) in which the stack formed by the plurality of electrochemical cells 32 is disposed. It is contemplated that the control unit 34 may be disposed at least partially on, in particular at least partially in, the housing. Alternatively, it is also contemplated that the cell system 30 may comprise an external unit (not shown here), wherein the external unit comprises at least a portion of the control unit 34. For example, the external unit may be a cloud, a server, or the like. It is also contemplated that the external unit comprises the storage element of the control unit 34. A computer program 36 is stored on the storage element, comprising instructions that, when the computer program 36 is executed by a computer, cause the computer to perform the cell parameter determination method of the cell system 30. The control unit 34 comprises the computer. Alternatively, it is also contemplated that the computer program 36 may be stored on a portable disk, for example, a USB stick, on a portable hard drive, on an optical disk, in particular on a CD or the like, in a cloud, on a server, or the like.

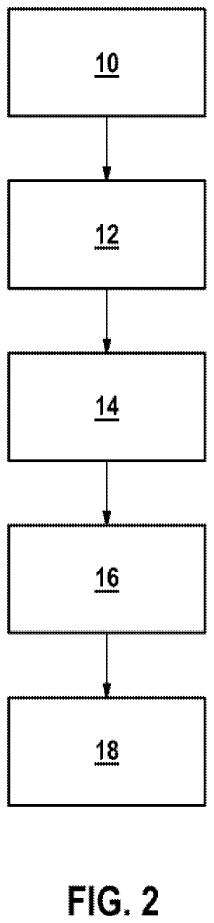

FIG. 2 shows a schematic procedure of the method for determining the cell parameter of the cell system 30, in particular the aging parameter, and for determining the plurality of further cell parameters, in particular the plurality of internal parameters. The cell parameter is the aging parameter of the cell system 30. A first cell parameter of the further cell parameters, in particular the internal parameters, comprises a temperature distribution in the cell system 30, in particular the first further cell parameter corresponds to the temperature distribution in the cell system 30.

A second cell parameter of the further cell parameters, in particular the internal parameters, comprises a current density distribution in the cell system 30, in particular the second further cell parameter corresponds to the current density distribution in the cell system 30. A third cell parameter of the further cell parameters, in particular the internal parameters, comprises a fluid distribution, in particular a hydrogen distribution, in the cell system 30, in particular the third further cell parameter corresponds to the hydrogen distribution in the cell system 30. A fourth cell parameter of the further cell parameters, in particular the internal parameters, comprises a fluid distribution, in particular an oxygen distribution, in the cell system 30, in particular the fourth further cell parameter corresponds to the oxygen distribution in the cell system 30.

The cell parameter is determined based on a physical model of the cell system 30 depending on operational parameters of the cell system 30. It is contemplated that the operational parameters will be transmitted to the external unit, for example wirelessly or via a cable, wherein the external unit preferably determines the at least one cell parameter of the cell system 30 based on the operational parameters of the cell system 30. The physical model is a simulation model of the cell system 30, which in particular describes a steady state operation of the cell system 30. The physical model is based on the finite element method. The physical model is unambiguously invertible with regard to the cell parameter, in particular the aging parameter. It is contemplated that the physical model may be unambiguously invertable with respect to the cell parameter, in particular the aging parameter, at least by filtering out physically irrelevant results of the physical model. For example, according to a publication by Zaccaria, Tucker and Traverso entitled “A distributed real-time model of degradation in a solid oxide fuel cell” (2016, Journal of Power Sources 311, 175-181), the physical model may describe a degradation of the cell system 30, wherein an ohmic portion of internal voltage losses is pre-factored with the aging parameter. Alternatively, it is also conceivable, for example, that other resistors of internal voltage losses differing from the ohmic portion, in particular the concentration losses or polarization losses, of the cell system 30 or an overall internal resistance of the cell system 30, are multiplied by the aging parameter as a pre-factor. In the preferred physical model, an overall specific surface resistance of the cell system 30 is multiplied by the aging parameter. The aging parameter describes an aging state of the cell system 30. The aging parameter has a value of 1 in an unaged state of the cell system 30 and a value greater than 1 in an aged state of the cell system 30. The aging parameter is a scalar parameter.

The physical model has multiple inputs and multiple outputs. Alternatively, it is also conceivable that the physical model only has one input parameter and/or only one output parameter. The input parameters of the physical model are at least partially operational parameters of the cell system 30. The operational parameters comprise a plurality of input parameters of the cell system 30, or alternatively, merely one input parameter of the cell system 30. The input parameters of the cell system 30 are operating parameters of the cell system 30, here by way of example a requested load current, a temperature, in particular a gas temperature, a volumetric flow rate, a gas composition, a pressure, a pressure difference, or the like. It is contemplated that the operating parameters are at least partially variables or control variables, in particular actual values or target values of the control variables, of the cell system 30. The input parameters of the physical model comprise the aging parameter of the cell system 30. The input parameters of the physical model comprise the operational parameters of the cell system 30.

The operational parameters comprise at least one output parameter of the cell system 30. It is also contemplated that the operational parameters may comprise a plurality of output parameters of the cell system 30. The output parameter of the cell system 30 comprises a performance parameter of the cell system 30. The performance parameter of the cell system 30 is an output voltage of the cell system 30, in particular of the stack formed by a plurality of electrochemical cells 32.

A first output parameter of the output parameters of the physical model comprises at least one of the operational parameters of the cell system 30, in particular the output parameter of the cell system 30. The first output parameter is the performance parameter of the cell system 30. Further output parameters of the physical model correspond to the further cell parameters of the cell system 30, in particular the further cell parameters of the cell system 30, preferably the first cell parameter, the second cell parameter, the third cell parameter and the fourth cell parameter of the further cell parameters. In particular, the physical model depicts a mapping which maps the inputs of the physical model, preferably the operating parameters of the cell system 30 and the aging parameter of the cell system 30 to the outputs of the physical model, preferably to the performance parameter of the cell system 30 and the further cell parameters of the cell system 30.

The operational parameters are sensed at least partially on the cell system 30 in a method step, in particular a sensing step 10. The cell system 30 comprises a sensing unit (not shown here) for at least partially sensing the operational parameters of the cell system 30. The sensing unit comprises a sensor unit for at least partially sensing the operational parameters. The sensing unit is configured to sense at least the output parameter configured as a performance parameter, in particular using sensors. For example, the sensor unit comprises at least one voltage sensor, in particular for sensing the performance parameter of the cell system 30 configured as the output voltage. The sensing unit is connected to the control unit 34 via data technology, in particular for wireless and/or wired data transmission. It is also contemplated that the control unit 34 at least partially comprises the sensing unit.

It is contemplated that the operational parameters configured as input parameters of the cell system 30 may be at least partially able to be sensed by means of the sensing unit, preferably using sensors. In addition or alternatively, it is also conceivable that the input parameters, in particular the input parameters configured as variables or control variables, preferably the target values of the control variables, are read at least in part directly by the control unit 34 in the sensing step 10, preferably by the control unit 34.

The operational parameters, in particular the input parameters and the output parameter, of the cell system 30 are recorded over time in the sensing step 10. Time series are formed based on the recorded operational parameters. The recorded operational parameters are stored as time series on the control unit 34, in particular on the storage element of the control unit 34.

In a method step, in particular in a selection step 12, a time is selected from the time series of the operational parameters, preferably by the control unit 34. The control unit 34 is provided to determine the cell parameters, in particular the aging parameter, for the selected point in time. The control unit 34 is provided to select the point in time from the time series of the operational variables such that a system state of the cell system 30 associated at the point in time can be described by the physical model. For example, it is conceivable that the physical model is only applicable to steady state conditions, in particular input parameters of the cell system 30, so that sufficient steady state operational parameters are to be used accordingly.

It is contemplated that the operational parameters associated at the time may be at least partially converted to match the physical model in a method step, in particular in a conversion step 14, preferably by the control unit 34. The operational parameters associated with the point in time are converted, in particular in the conversion step 14, to the input parameters and/or output parameters of the physical model as needed. It is also contemplated that the operational parameters may be at least partially pre-processed, for example oscillations or the like may be removed by a filter. It is further contemplated that the operational parameters will be at least partially aggregated, in particular in the conversion step 14.

Based on the physical model, in a method step, in particular in a determination step 16, the cell parameter is determined at the selected time for which the physical model, together with the input parameters, predicts the sensed output parameter, in particular the performance parameter at the selected time. In order to determine the cell parameter, the physical model is inverted and optimized in the determination step 16, in particular with regard to the cell parameter. In the determination step 16, an optimization method is applied to determine the cell parameters, for example a Bayesian optimization, a simulated annealing method, a gradient method, or the like, in particular regarding the sensed output parameter of the cell system 30 at the input parameters of the selected point in time and the output parameter predicted by the physical model at the input parameters of the selected point in time.

In a method step, in particular in an evaluation step 18, a time curve of the aging parameter of the cell system 30 is determined. In order to determine the time curve for the aging parameter, the selection step 12, if necessary the conversion step 14 and the determination step 16 are performed at least a second time, wherein in the selection step 12 a point in time different from the point in time previously selected is selected from the time series of the operational variables. The aging parameter is determined as a function of the operational parameters of the cell system 30 based on the physical model at the further point in time, in particular at a plurality of further points in time, from the time series of the operational parameters, in particular analogously to the determination of the aging parameter at the previously selected time from the time series of the operational parameters of the cell system 30. Based on the determined aging parameter at different times, the curve of the aging parameter over time can be determined, in particular can be shown. It is contemplated that the curve of the aging parameter over time is extrapolated, in particular to predict a future course of the aging parameter. It is also contemplated that the curve of the aging parameter over time is related to at least one, preferably age-relevant, operational parameter of the cell system 30 and/or to one of the further cell parameters of the cell system 30.

It is also contemplated that the physical model will be used to train a regression model. The regression model is trained on the basis of results determined using the physical model, in particular on the basis of the cell parameters determined, for example by means of statistical experimental planning. In order to train the regression model, a statistical experimental plan is generated from a combination of the operational parameters, for which the cell parameters are determined based on the physical model, wherein results are in particular used to train the regression model. For example, the training of the regression model is based on linear regression, on a random forest, on a Gaussian process, on a neural network, on an explainable boosting machine, or the like. The regression model is intended to replace the physical model in an alternative determination step 16. The at least one cell parameter of the cell system 30 is determined, in particular in the alternative determination step 16, using the regression model. The regression model is provided, in particular in the alternative determining step 16, for use in an optimization method for determining the cell parameters or for directly determining the cell parameters. In particular, it is contemplated that the regression model is trained such that the regression model determines the at least one cell parameter of the cell system 30 directly from the operational parameters, preferably the at least one input parameter and the at least one output parameter, preferably in the alternative determination step 16, wherein in particular an inversion of the physical model, preferably at least in the determination step 16, is omitted.

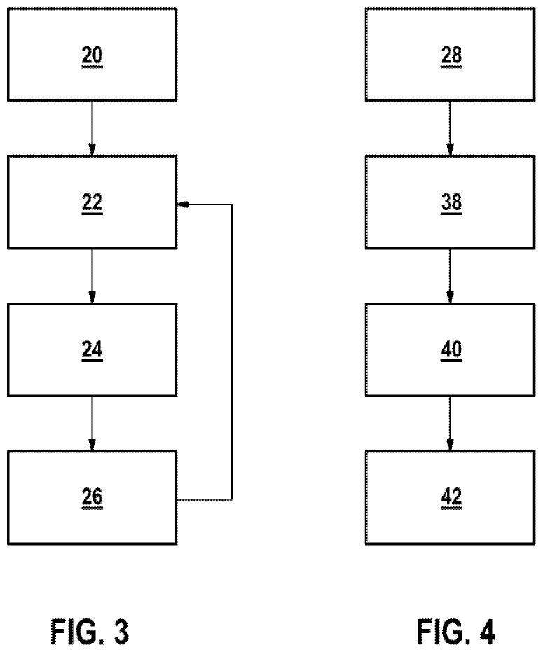

Active learning, in particular safe active learning, is used to train the regression model. The statistical experimental plan is generated by active learning. Alternatively, it is also conceivable that the statistical experimental plan is generated by means of Latin hypercube sampling or the like. FIG. 3 shows a schematic procedure for training the regression model.

Active learning is used to select training data with optimal information for training the regression model. Safe active learning is used to avoid training data at which the physical model does not converge, in particular at which it diverges. For example, when determining the cell parameters, a convergence parameter is determined. The convergence parameter is an indicator of how close, in particular numerically, a solution method for the physical model was to not converging, in particular to diverging. For example, the convergence parameter may be determined based on a required number of iterations of the optimization method for determining the cell parameter, in particular the aging parameter. Alternatively, it is also conceivable that the convergence parameter is determined as a function of the physical model's output parameters, in particular as a function of the at least one output parameter of the cell system 30 and/or as a function of the internal parameters.

In an initialization step 20 of the training of the regression model, operational parameters of the cell system 30 are selected to initialize the training of the regression model to a system state of the cell system 30 for which it is known that the physical model solution method converges. Based on the physical model, in particular through an inversion and optimization of the physical model, the cell parameter variable is determined for the operational parameters selected in the initialization step 20. Based on results of the initialization step 20, in particular based on the operational parameters selected in the initialization step 20 and the cell parameter determined in the initialization step 20, a value for the convergence parameter associated with the results is determined. Based on the results from the initialization, in particular based on the operational parameters selected in the initialization step 20, the regression model, preferably a probabilistic one, preferably a Gaussian process model, is trained. In addition, a safety model, in particular a probabilistic one, preferably a Gaussian process model, is trained based on the value for the convergence parameter determined in the initialization step 20.

After the initialization step 20, a loop is executed to train the regression model, in particular via the control unit 34. The loop comprises a first loop step 22 in which operational parameters are selected for a further system state of the cell system 30, which preferably have a maximum value for an information content and with which the method of solving the physical model converges with a probability that is above a probability threshold. Very particularly preferably, the probability threshold is 0.5. Alternatively, however, it is also conceivable that the probability threshold is between 0.1 and 0.9, preferably between 0.2 and 0.8, preferably between 0.3 and 0.7, particularly preferably between 0.4 and 0.6. However, further alternatively, it is also conceivable that the probability threshold is outside a value range of between 0.1 and 0.9. The information content is evaluated via entropy, which is proportional to the predictive variance, especially in the case of Gaussian processes. In particular, a limited optimization problem arises in which operational parameters are calculated, in which the information content has a maximum value and the probability of convergence of the solution method for the physical model is greater than the probability threshold.

The probability threshold is adjustable by an operator, for example via an input unit (not shown here). The input unit is in particular connected or connectable to the control unit 34 via data technology, preferably for wireless and/or wired data transmission. For example, the input unit may be configured as a keyboard, a keypad, a touch screen, a rotary dial, a slider, a push button, or the like. It is contemplated that the control unit 34 or the external unit may comprise the input unit. As an alternative to the probability of convergence of the solution method for the physical model for determining the cell parameters, a criterion is also conceivable that a probability for an interference-free simulation using the physical model is greater than the probability threshold. The probability of a fault-free simulation using the physical model considers the convergence of the solution method for the physical model, memory requirements, processor requirements, and a simulation duration. Alternatively, or in addition, a distance of the cell parameters determined by the physical model from known physical limits can also be used as an indicator of the probability of a fault-free simulation.

In a second loop step 24 of the loop, the cell parameter and a corresponding value for the convergence parameter are determined with the operational parameters of the further system state. In a third loop step 26 of the loop, the regression model and/or the safety model is updated as a function of the cell parameter determined in the second loop step 24 and/or as a function of the convergence parameter determined to the further system state of the cell system 30. If no termination criterion is satisfied after the third loop step 26, the loop begins again with the first loop step 22. For example, the termination criterion may be an exhaustion of the computational time, an exhaustion of a number of evaluated system states of the cell system 30, a drop of the information content below a threshold value for the information content, or a drop of a maximum error on a validation data set to below a threshold.

The further cell parameters, in particular the internal parameters, of the cell system 30 are determined as a function of the determined cell parameter, in particular in the determining step 16. The further cell parameters, which are in particular output parameters of the physical model, are determined based on the physical model as a function of the regression model determined based on the physical model, in particular by inverting and optimizing the physical model with respect to the aging parameter or by the regression model generated by means of the physical model.

It is contemplated that the further cell parameters, in particular the internal parameters, will be determined at least partially in a spatially resolved manner, preferably in the determination step 16. In particular, preferably in the determination step 16, the respective local distribution of the further cell parameters is determined. The respective local distribution of the further cell parameters is a local distribution of values for the respective further cell parameters within the cell system 30, in particular within the stack formed from a plurality of electrochemical cells 32. The respective local distribution of the further cell parameters is determined based on the physical model as a function of operational parameters of the cell system 30, preferably via the optimization method applied to the inverted physical model or via the regression model generated by the physical model. The further cell parameters may each be determined at a position or at a list of positions in the cell system 30. It is also contemplated that a combination of the further cell parameters, in particular internal parameters, of the cell system 30, for example a product, a sum, a non-linear function or the like, may be determined at the position or at the list of positions in the cell system 30. It is also contemplated that that derived values of the respective further cell parameters, in particular the respective internal parameters, or the combination of the further cell parameters, in particular the combination of internal parameters, such as a maximum, a minimum an average in a partial volume or in a total volume of the cell system 30, are determined to describe the local distribution, for example, a first degree surface torque, a second degree surface torque, support points of a cumulative distribution density or the like, gradients or rates of change.

FIG. 4 shows a schematic procedure for training and applying a failure detection model to the cell system 30. The physical model is used to generate training data for the failure detection model. In particular, at least partially critical value ranges are specified for the further cell parameters, in particular the internal parameters, which are stored on the storage element of the control unit 34, for example. It is contemplated that the critical value ranges may be adjustable, for example, automatically by the control unit 34 or manually by the operator via the input unit. The physical model may be used to determine the operational parameters for which at least one of the further cell parameters is in the critical value range. In a data generation step 28, a database is determined with the operational parameters and the associated values of the internal parameters determined based on the physical model. For example, the database is stored on the memory element of control unit 34. The failure detection model can be purposefully trained using the database with operational parameters in which the respective associated value of the further cell parameters is within or outside the critical value range. For example, the failure detection model is trained by machine learning, in particular to perform a classification method for classifying determinable failure states of the cell system 30. For example, the training of the failure detection model is based on a random forest, on a support vector machine, on a neural network, or the like.

The failure detection model is used in the operation of the cell system 30 to detect and, in particular, classify a failure state in the cell system 30 based on the operational parameters of the cell system 30 sensed in operation, for instance to assign it to one of the further cell parameters.

1. A method for determining at least one cell parameter, of a cell system (30) comprising at least one electrochemical cell (32), wherein the cell parameter is determined based on a physical model of the cell system (30) as a function of the operational parameters of the cell system (30).

2. The method of claim 1, wherein the operational parameters comprise at least one input parameter of the cell system (30).

3. The method of claim 2, wherein input parameter comprises at least one operating parameter of the cell system (30).

4. The method according to claim 1, wherein the operational parameters comprise at least one output parameter of the cell system (30).

5. The method of claim 4, wherein the output parameter comprises at least one performance parameter of the cell system (30).

6. The method according to claim 1, wherein the operational parameters are at least partially sensed on the cell system (30).

7. The method according to claim 1, wherein time series are formed based on the operating parameters.

8. The method according to claim 1, wherein the physical model is inverted and optimized to determine the cell parameter.

9. The method according to claim 1, wherein the physical model is used to train a regression model.

10. The method of claim 9, wherein active learning is used to train the regression model.

11. The method according to claim 1, wherein a curve of an aging parameter over time of the cell system (30) is determined.

12. The method according to claim 1, wherein at least one further cell parameter of the cell system (30) is determined as a function of the determined cell parameter.

13. The method of claim 12, wherein the at least one further cell parameter is determined in a spatially resolved manner.

14. The method of claim 12, wherein the at least one further cell parameter comprises a temperature distribution in the cell system (30).

15. The method according to claim 12, wherein the at least one further cell parameter comprises a fluid distribution in the cell system (30).

16. The method according to claim 12, wherein the at least one further cell parameter comprises a current density distribution in the cell system (30).

17. The method of claim 1, wherein the physical model is used to generate training data for a failure detection model.

18. A cell system (30) having at least one electrochemical cell (32) and having at least one control unit (34) for performing a method according claim 1.

19. A non-transitory computer-readable medium comprising instructions which, when executed by a computer, prompt the latter to perform the method according to claim 1.
